(19) United States
(12) Patent Application Publication
(10) Pub. No.: US 2025/0318376 A1
(43) Pub. Date: Oct. 9, 2025

(54) DISPLAY DEVICE

(71) Applicant: Samsung Display Co., Ltd., Yongin-Si (KR)

(72) Inventors: Se Ho LEE, Yongin-si (KR); Tae Hyung KIM, Yongin-si (KR); Jung Ho LEE, Yongin-si (KR)

(21) Appl. No.: 18/970,901

(22) Filed: Dec. 6, 2024

(30) Foreign Application Priority Data
Apr. 5, 2024 (KR) 10-2024-0046411

(51) Int. Cl. H10K 59/131; H10K 59/122; H10K 59/80

(52) U.S. Cl. CPC H10K 59/131; H10K 59/122; H10K 59/80522

(57) ABSTRACT

A display device includes light emitting elements including a first electrode disposed in a second metal layer, a second electrode disposed in a third metal layer, and a light emitting material disposed in a light emitting layer. A first metal layer includes a first voltage line providing a first voltage to the second electrode, an insulating film includes a first opening extending to a surface of the first voltage line, the second metal layer includes an auxiliary electrode connected to the first voltage line through the first opening, a pixel defining film includes a second opening extending to a surface of the auxiliary electrode, the light emitting layer includes a third opening extending to the surface of the auxiliary electrode, the second electrode is connected to the auxiliary electrode through the second opening and the third opening, and the first and third openings overlap the second opening.

### CROSS-REFERENCE TO RELATED APPLICATION

This application claims priority from Korean Patent Application No. 10-2024-0046411 filed on Apr. 5, 2024, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device.

### 2. Description of the Related Art

The importance of display devices has steadily increased with the development of multimedia technology. Along with this trend, various types of display devices such as a liquid crystal display (LCD) device, an organic light emitting diode (OLED) display device and the like have been developed.

Among the display devices, a self-light emitting display device includes a self-light emitting element such as an organic light emitting element. The self-light emitting element may include two opposite electrodes and a light emitting layer interposed therebetween. In the case of using the organic light emitting element as the self-light emitting element, the electrons and holes from the two electrodes are recombined in the light emitting layer to produce excitons, which transition from the excited state to the ground state, emitting light.

The self-light emitting display device is attracting attention as a next-generation display device because of being able to meet the high display quality requirements such as wide viewing angle, high brightness and contrast, and quick response speed as well as being able to be made having a low power consumption, lightweight, and thin due to no necessity of a power source such as a backlight unit.

### SUMMARY

Aspects of the present disclosure provide a display device capable of minimizing a voltage drop (IR-drop) phenomenon.

Aspects of the present disclosure also provide a display device that secures a laser drilling process margin for a high-resolution panel.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device including a substrate, a first metal layer disposed on the substrate, a first insulating film disposed on the first metal layer, a second metal layer disposed on the first insulating film, a pixel defining film disposed on the second metal layer, a light emitting layer disposed on the pixel defining film, a third metal layer disposed on the light emitting layer, and a plurality of light emitting elements including a first electrode disposed in the second metal layer, a second electrode disposed in the third metal layer, and a light emitting material disposed in the light emitting layer. The first metal layer includes a first voltage line providing a first voltage to the second electrode. The first insulating film includes a first opening extending to at least a part of a top surface of the first voltage line. The second metal layer includes an auxiliary electrode connected to the first voltage line through the first opening. The pixel defining film includes a second opening extending to at least a part of a top surface of the auxiliary electrode. The light emitting layer includes a third opening extending to at least a part of the top surface of the auxiliary electrode. The second electrode is connected to the auxiliary electrode through the second opening and the third opening. Each of the first opening and the third opening overlaps the second opening.

In an embodiment, each of an entire portion of the first opening and an entire portion of the third opening overlaps the second opening.

In an embodiment, each of a width of the first opening and a width of the third opening is smaller than a width of the second opening.

In an embodiment, at least a part of the first opening overlaps the third opening.

In an embodiment, an entire portion of the first opening overlaps the third opening.

In an embodiment, the first opening and the third opening do not overlap.

In an embodiment, the third opening is formed by a laser drilling process.

In an embodiment, the first opening and the second opening are formed by a photolithography process.

In an embodiment, the display device may further comprise a second insulating film disposed between the first metal layer and the first insulating film. The second insulating film comprises a fourth opening extending to at least a part of the top surface of the first voltage line, and a width of the fourth opening is greater than a width of the first opening.

In an embodiment, the auxiliary electrode is not in contact with the second insulating film.

In an embodiment, the light emitting layer is disposed entirely over the plurality of light emitting elements.

According to an aspect of the present disclosure, there is provided a display device including a substrate, and a light emitting element layer disposed on the substrate. The light emitting element layer includes a plurality of light emitting elements including a first electrode, a light emitting layer disposed on the first electrode, and a second electrode disposed on the light emitting layer, and a pixel defining film extending to at least a part of a top surface of the first electrode. The display device further includes a first voltage line disposed between the substrate and the light emitting element layer, and providing a first voltage to the second electrode, and an auxiliary electrode disposed in a same layer as the first electrode, and connecting the first voltage line to the second electrode. The second electrode and the auxiliary electrode are in contact with each other through a first opening of the pixel defining film and a second opening of the light emitting layer. Each of a first region where the first voltage line and the auxiliary electrode are in contact with each other and a second region where the second electrode and the auxiliary electrode are in contact with each other overlaps a third region where the first opening is disposed.

In an embodiment, each of an entire portion of the first region and an entire portion of the second region overlaps the third region.

In an embodiment, each of a width of the first region and a width of the second region is smaller than a width of the third region.

In an embodiment, at least a part of the first region overlaps the second region.

In an embodiment, an entire portion of the first region overlaps the second region.

In an embodiment, the first region and the second region do not overlap.

In an embodiment, the second region is formed by a laser drilling process.

In an embodiment, the first region and the third region are formed by a photolithography process.

In an embodiment, the light emitting layer is disposed entirely over the plurality of light emitting elements.

In a display device according to an embodiment of the present disclosure, a voltage drop (IR-drop) phenomenon can be minimized.

In the display device according to an embodiment of the present disclosure, a laser drilling process margin for a high-resolution panel can be secured.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings.

FIG. 1 is a perspective view showing a display device according to an embodiment.

FIG. 2 is a cross-sectional view taken along line X1-X1′ of FIG. 1.

FIG. 3 is a cross-sectional view showing a display device according to an embodiment.

FIG. 4 is a plan view showing a state in which a connection film is attached to a wiring pad of a display device according to an embodiment.

FIG. 5 is a plan view showing a state in which a connection film is not attached to a wiring pad of a display device according to an embodiment.

FIG. 6 is a diagram illustrating pixels and wires of a display device according to an embodiment.

FIG. 7 is a plan view schematically illustrating a part of a display area of a display substrate according to an embodiment.

FIG. 8 is a cross-sectional view taken along line X2-X2′ of FIG. 7 according to an embodiment.

FIG. 9 is an equivalent circuit diagram of a pixel according to an embodiment.

FIG. 10 is a cross-sectional view showing an example of a first transistor of a circuit layer according to an embodiment.

FIG. 11 is a cross-sectional view showing an example of a second transistor and a third transistor of a circuit layer according to an embodiment.

FIG. 12 is a cross-sectional view taken along line X3-X3′ of FIG. 7 according to an embodiment.

FIG. 13 is a cross-sectional view showing a process of removing a part of a light emitting layer through a laser drilling process.

FIG. 14 is a plan view schematically showing a part of a display area of a display substrate according to a comparative example.

FIG. 15 is a cross-sectional view taken along line X4-X4′ of FIG. 14.

FIG. 16 is a plan view schematically illustrating a part of a display area of a display substrate according to an embodiment.

FIG. 17 is a cross-sectional view taken along line X5-X5′ of FIG. 16.

### DETAILED DESCRIPTION OF THE EMBODIMENTS

The inventive concept will now be described more fully hereinafter with reference to the accompanying drawings, in which embodiments of the inventive concept are shown. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments of the present disclosure will be described in detail with reference to the accompanying drawings.

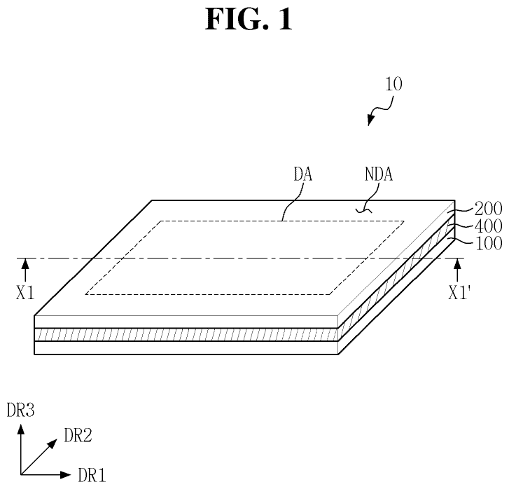

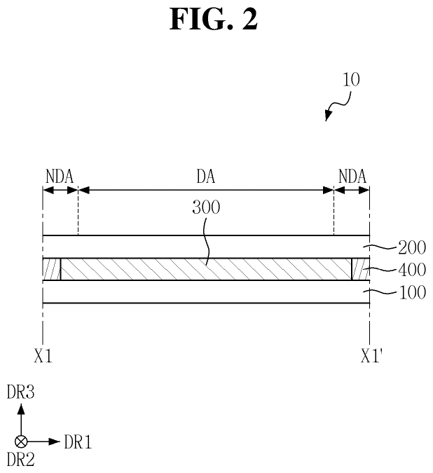

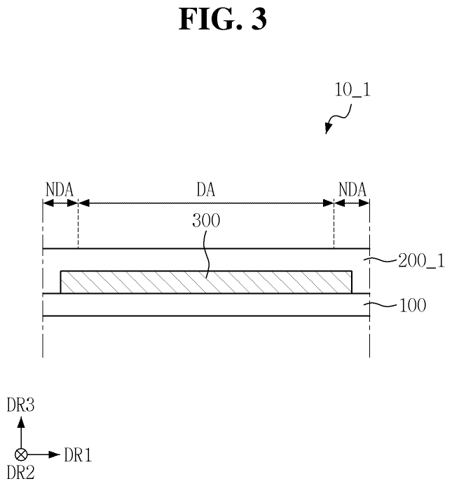

FIG. 1 is a perspective view showing a display device 10 according to an embodiment. FIG. 2 is a cross-sectional view taken along line X1-X1′ of FIG. 1. FIG. 3 is a cross-sectional view showing a display device 10_1 according to an embodiment.

Referring to FIGS. 1 to 2, the display device 10 may be applied to a variety of electronic apparatuses, i.e., medium-or small-sized electronic devices such as a tablet PC, a smartphone, a car navigation unit, a camera, a center information display (CID) provided in a vehicle, a wristwatch-type electronic device, a personal digital assistant (PDA), a portable multimedia player (PMP) and a game console, and medium and large electronic devices such as a television, an external billboard, a monitor, a personal computer and a laptop computer. These are merely suggested as examples, but the display device 10 may also be applied to other electronic devices without departing from the present disclosure.

In an embodiment, the display device 10 may have a rectangular shape in plan view. The display device 10 may include two long sides extending in a first direction DR1 and two short sides extending in a second direction DR2 intersecting the first direction DR1. A corner where the long side and the short side of the display device 10 meet may have a right angle. However, the present disclosure is not limited thereto, and the corner may have a curved surface. In an embodiment, the long side may extend in the second direction DR2, and the short side may extend in the first direction DR1. The planar shape of the display device 10 is not limited to the exemplified one, but may have a circular shape or other shapes.

In the illustrated figure, the first direction DR1 and the second direction DR2 cross each other as horizontal directions. For example, the first direction DR1 and the second direction DR2 may be orthogonal to each other. In addition, a third direction DR3 crosses the first direction DR1 and the second direction DR2, and may be, for example, perpendicular directions orthogonal to each other. Unless otherwise defined, in the present specification, directions indicated by arrows of the first to third directions DR1, DR2, and DR3 may be referred to as one side, and the opposite directions thereto may be referred to as the other side. Also, the terms “above,” “upper side,” “upper portion,” “top,” and “top surface,” as used herein, refer to a direction indicated by an arrow in the drawing in the third direction DR3 based on the drawings, and the terms “below,” “lower side,” “lower portion,” “bottom,” and “bottom surface,” as used herein, refer to a direction opposite to the direction indicated by the arrow in the third direction DR3 based on the drawings.

The display device 10 may include a display area DA displaying an image and a non-display area NDA not displaying an image. In an embodiment, the non-display area NDA may be located around the display area DA and may surround the display area DA.

In an embodiment, as shown in FIG. 2, the display device 10 may include, as a schematic stacked structure, a display substrate 100 and a color conversion substrate 200 facing the display substrate 100, and may further include a sealing portion 400 for coupling the display substrate 100 and the color conversion substrate 200, and a filler 300 filled between the display substrate 100 and the color conversion substrate 200.

The display substrate 100 may include elements and circuits for displaying an image, for example, a pixel circuit such as a switching element, a pixel defining film and a self-light emitting element that define an emission area and a non-emission area, which will be described later, in the display area DA. In an embodiment, the self-light emitting element may include at least one of an organic light emitting diode, a quantum dot light emitting diode, an inorganic micro light emitting diode (e.g., micro LED), or an inorganic nano light emitting diode (e.g., nano LED). Hereinafter, for simplicity of description, a case where the self-light emitting element is an organic light emitting element will be described as an example.

The color conversion substrate 200 may be disposed above the display substrate 100, facing the display substrate 100. In an embodiment, the color conversion substrate 200 may include a color conversion pattern for converting the color of incident light. In an embodiment, the color conversion pattern may include at least one of a color filter and a wavelength conversion pattern.

The sealing portion 400 may be positioned between the display substrate 100 and the color conversion substrate 200 in the non-display area NDA. The sealing portion 400 may be disposed along edges of the display substrate 100 and the color conversion substrate 200 in the non-display area NDA to surround the display area DA in plan view. The display substrate 100 and the color conversion substrate 200 may be bonded to each other through the sealing portion 400.

In an embodiment, the sealing portion 400 may be made of an organic material. For example, the sealing portion 400 may be made of an epoxy-based resin, but is not limited thereto.

The filler 300 may be positioned in a space surrounded by the sealing portion 400 between the display substrate 100 and the color conversion substrate 200. The filler 300 may fill the space between the display substrate 100 and the color conversion substrate 200.

In an embodiment, the filler 300 may be made of a material that can transmit light. In an embodiment, the filler 300 may be made of an organic material. For example, the filler 300 may be formed of a silicon-based organic material, an epoxy-based organic material, or the like, but is not limited thereto. In an embodiment, the filler 300 may be omitted.

In an embodiment, the display device 10_1 may not include the sealing portion 400, as shown in FIG. 3. For example, a color conversion substrate 200_1 of the display device 10_1 may be an encapsulation substrate. The color conversion substrate 200_1 may include a protrusion portion disposed along the outer edge of the color conversion substrate 200_1 and protruding toward the display substrate 100 in the third direction DR3, and a recess portion surrounded by the protrusion portion. The internal space may be sealed by the display substrate 100, the color conversion substrate 200_1, and the protrusion portion. The filler 300 may be filled in the recess portion.

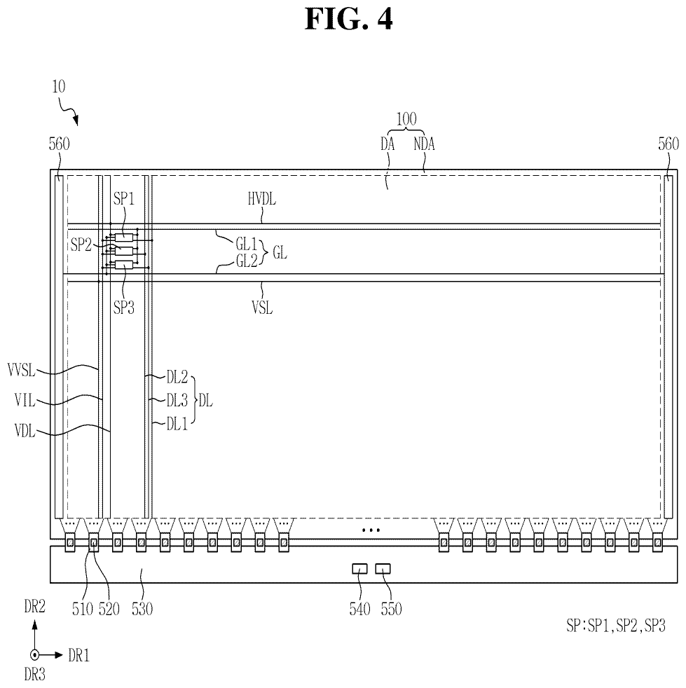

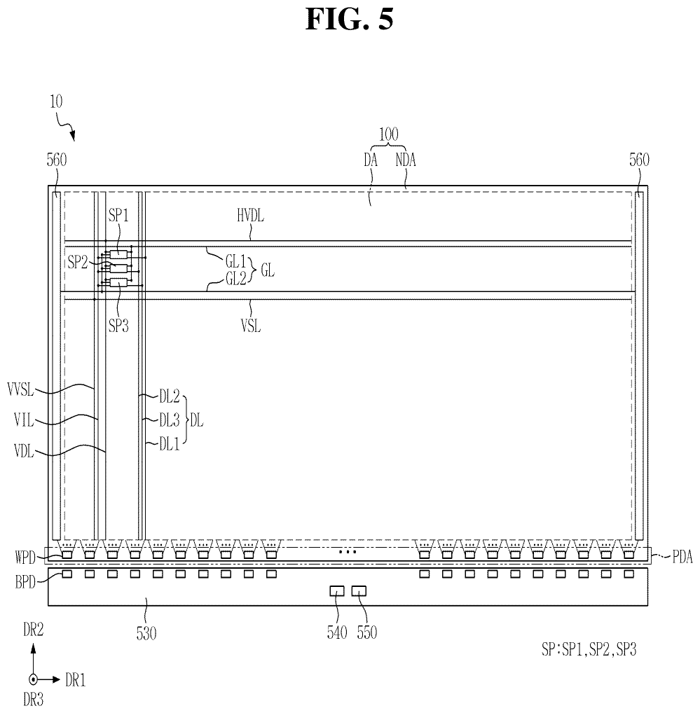

FIG. 4 is a plan view showing a state in which a connection film 510 is attached to a wiring pad of a display device 10 according to an embodiment. FIG. 5 is a plan view showing a state in which a connection film is not attached to a wiring pad WPD of a display device 10 according to an embodiment.

Referring to FIGS. 4 and 5, the display device 10 may include the display substrate 100, the connection film 510, a display driver 520, a circuit board 530, a timing controller 540, a power supply unit 550, and a gate driver 560.

The display substrate 100 may have a rectangular shape in plan view. For example, the display substrate 100 may have a rectangular shape, in plan view, having a long side in the first direction DR1 and a short side in the second direction DR2. A corner where the long side in the first direction DR1 and the short side in the second direction DR2 meet may be right-angled or rounded with a predetermined curvature. The planar shape of the display substrate 100 is not limited to the rectangular shape, and may be formed in another polygonal shape, a circular shape or an elliptical shape. For example, the display substrate 100 may be formed to be flat, but is not limited thereto. In another example, the display substrate 100 may be bent with a predetermined curvature.

The display substrate 100 may include the display area DA and the non-display area NDA.

The display area DA, which is an area for displaying an image, may be defined as the central area of the display substrate 100. In an embodiment, the display area DA may include a pixel SP, a gate line GL, a data line DL, an initialization voltage line VIL, a first voltage line VDL, a horizontal voltage line HVDL, a vertical voltage line VVSL, and a second voltage line VSL.

The pixel SP may be formed in each pixel area at intersections of the data lines DL and the gate lines GL. In an embodiment, the pixels SP may include first to third pixels SP1, SP2, and SP3. Each of the first to third pixels SP1, SP2, and SP3 may be connected to the gate line GL and the data line DL. Each of the first to third pixels SP1, SP2, and SP3 may be defined as a minimum unit area that outputs light.

Each of the first to third pixels SP1, SP2, and SP3 may include an organic light emitting diode (OLED) having an organic light emitting layer, a quantum dot light emitting diode (LED) including a quantum dot light emitting layer, a micro LED, or an inorganic LED having an inorganic semiconductor.

The first pixel SP1 may emit light of a first color such as red light, the second pixel SP2 may emit light of a second color such as green light, and the third pixel SP3 may emit light of a third color such as blue light. The pixel circuits of the first pixel SP1, the second pixel SP2, and the third pixel SP3 may be sequentially arranged in the opposite direction of the second direction DR2, but the arrangement direction of the pixel circuits is not limited thereto.

The gate line GL may include a first gate line GL1 and a second gate line GL2. The first gate lines GL1 may extend in the first direction DR1 and may be spaced apart from each other in the second direction DR2. The first gate line GL1 may receive a first gate signal from the gate driver 560 and supply the first gate signal to the first to third pixels SP1, SP2, and SP3.

The second gate lines GL2 may extend in the first direction DR1 and may be spaced apart from each other in the second direction DR2. The second gate line GL2 may receive a second gate signal from the gate driver 560 and supply the second gate signal to the first to third pixels SP1, SP2, and SP3.

The data lines DL may extend in the second direction DR2 and may be spaced apart from each other in the first direction DR1. The data lines DL may include first to third data lines DL1, DL2, and DL3. Each of the first to third data lines DL1, DL2, and DL3 may supply a data voltage to each of the first to third pixels SP1, SP2, and SP3.

The initialization voltage lines VIL may extend in the second direction DR2 and may be spaced apart from each other in the first direction DR1. The initialization voltage line VIL may supply the initialization voltage received from the display driver 520 to the pixel circuit of each of the first to third pixels SP1, SP2 and SP3. The initialization voltage line VIL may receive a sensing signal from the pixel circuit of each of the first to third pixels SP1, SP2 and SP3 to supply the sensing signal to the display driver 520.

The first voltage lines VDL may extend in the second direction DR2 and may be spaced apart from each other in the first direction DR1. The first voltage line VDL may supply a driving voltage or a high potential voltage received from the power supply unit 550 to the first to third pixels SP1, SP2, and SP3.

The horizontal voltage lines HVDL may extend in the first direction DR1 and may be spaced apart from each other in the second direction DR2. The horizontal voltage line HVDL may be connected to the first voltage line VDL. The horizontal voltage line HVDL may receive a driving voltage or a high potential voltage from the first voltage line VDL.

The vertical voltage lines VVSL may extend in the second direction DR2 and may be spaced apart from each other in the first direction DR1. The vertical voltage line VVSL may be connected to the second voltage line VSL. The vertical voltage line VVSL may supply a low potential voltage received from the power supply unit 550 to the second voltage line VSL.

The second voltage lines VSL may extend in the first direction DR1 and may be spaced apart from each other in the second direction DR2. The second voltage line VSL may supply a low potential voltage to the first to third pixels SP1, SP2, and SP3.

The connection relationship of the pixel SP, the gate line GL, the data line DL, the initialization voltage line VIL, the first voltage line VDL, the horizontal voltage line HVDL, the vertical voltage line VVSL, and the second voltage line VSL may be designed and changed in various ways according to the number and arrangement of the pixels SP.

The non-display area NDA may be defined as the remaining area of the display substrate 100 except the display area DA. For example, the non-display area NDA may include fan-out lines connecting the data line DL, the initialization voltage line VIL, the first voltage line VDL, and the vertical voltage line VVSL to the display driver 520, the gate driver 560, and the wiring pad WPD connected to the connection film 510.

The non-display area NDA may include a pad area PDA, which is an area where the wiring pad WPD is disposed. The pad area PDA may be located adjacent to one side of the display device 10. For example, the pad area PDA may be located adjacent to the lower side of the display device 10. In an embodiment, the pad area PDA may extend along the first direction DR1.

The connection film 510 may be connected to the wiring pad WPD disposed on the lower side of the non-display area NDA and a board pad BPD disposed on the upper side of the circuit board 530. For example, input terminals, such as bumps, provided on one side and the other side of the connection film 510 may be attached to the wiring pad WPD and the board pad BPD through a film attachment process. For example, the connection film 510 may be bent like a tape carrier package or a chip on film. The connection film 510 may be bent toward the lower portion of the display substrate 100 to reduce the bezel area of the display device 10.

The display driver 520 may be mounted on the connection film 510. For example, the display driver 520 may be implemented as an integrated circuit (IC). The display driver 520 may receive digital video data and a data control signal from the timing controller 540, and according to the data control signal, convert the digital video data to an analog data voltage to supply it to the data lines DL through the fan-out lines.

The circuit board 530 may support the timing controller 540 and the power supply unit 550, and supply signals and power to the display driver 520. For example, the circuit board 530 may supply a signal supplied from the timing controller 540 and a power voltage supplied from the power supply unit 550 to the connection film 510 and the display driver 520 through the board pad BPD to display an image on each pixel. To this end, a signal line and a power line may be provided on the circuit board 530.

The timing controller 540 may be mounted on the circuit board 530 and receive image data and a timing synchronization signal supplied from the display driving system or a graphic device through a user connector provided on the circuit board 530. The timing controller 540 may generate digital video data by aligning the image data to fit the pixel disposition structure based on the timing synchronization signal, and may supply the generated digital video data to the display driver 520. The timing controller 540 may generate the data control signal and the gate control signal based on the timing synchronization signal. The timing controller 540 may control the data voltage supply timing of the display driver 520 based on the data control signal, and may control the gate signal supply timing of the gate driver 560 based on the gate control signal.

The power supply unit 550 may be disposed on the circuit board 530 to supply a power voltage to the connection film 510 and the display driver 520. For example, the power supply unit 550 may generate a driving voltage or a high potential voltage and supply it to the first voltage line VDL, may generate a low potential voltage and supply it to the vertical voltage line VVSL, and may generate an initialization voltage and supply it to the initialization voltage line VIL.

The gate driver 560 may be disposed on at least one of the left and right sides of the non-display area NDA. The gate driver 560 may generate a gate signal based on the gate control signal supplied from the timing controller 540. The gate control signal may include a start signal, a clock signal, and a power voltage, but the present disclosure is not limited thereto. The gate driver 560 may supply a gate signal to the gate line GL according to a set order.

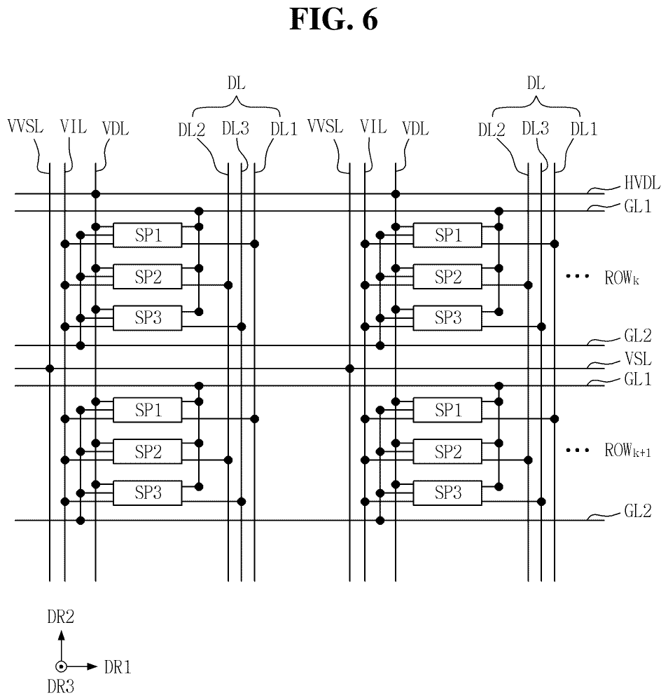

FIG. 6 is a diagram illustrating pixels SP and wires of a display device according to an embodiment.

Referring to FIG. 6 in addition to FIGS. 4 and 5, the pixels SP may include first to third pixels SP1, SP2, and SP3. The pixel circuits of the first pixel SP1, the second pixel SP2, and the third pixel SP3 may be sequentially arranged in the opposite direction of the second direction DR2, but the arrangement order of the pixel circuits is not limited thereto.

Each of the first to third pixels SP1, SP2, and SP3 may be connected to the first voltage line VDL, the initialization voltage line VIL, the gate line GL, and the data line DL.

The first voltage line VDL may extend in the second direction DR2. The first voltage line VDL may be disposed on the left side of the pixel circuits of the first to third pixels SP1, SP2 and SP3. The first voltage line VDL may supply a driving voltage or high potential voltage to a transistor of each of the first to third pixels SP1, SP2 and SP3.

The horizontal voltage line HVDL may extend in the first direction DR1. The horizontal voltage line HVDL may be disposed above the first gate line GL1 disposed in a k^{th} row ROWₖ (k being a positive integer). The horizontal voltage line HVDL may be connected to the first voltage line VDL. The horizontal voltage line HVDL may receive a driving voltage or a high potential voltage from the first voltage line VDL.

The initialization voltage line VIL may extend in the second direction DR2. The initialization voltage line VIL may be disposed on the left side of the auxiliary line of the second gate line GL2, which is branched in the second direction DR2. The initialization voltage line VIL may be disposed between the auxiliary line of the second gate line GL2, which is branched in the second direction DR2, and the vertical voltage line VVSL. The initialization voltage line VIL may supply an initialization voltage to the pixel circuit of each of the first to third pixels SP1, SP2, and SP3. The initialization voltage line VIL may receive a sensing signal from the pixel circuit of each of the first to third pixels SP1, SP2 and SP3 to supply the sensing signal the display driver 520.

The vertical voltage line VVSL may extend in the second direction DR2. The vertical voltage line VVSL may be disposed on the left side of the initialization voltage line VIL. The vertical voltage line VVSL may be connected between the power supply unit 550 and the second voltage line VSL. The vertical voltage line VVSL may supply the low potential voltage supplied from the power supply unit 550 to the second voltage line VSL.

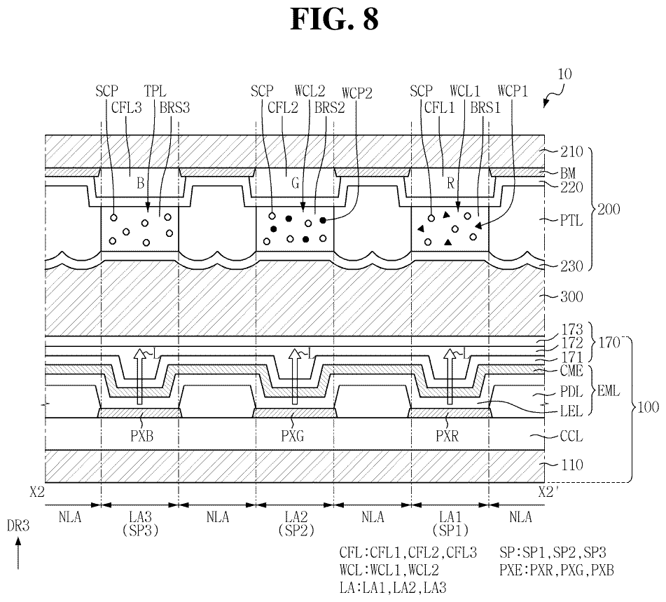

The second voltage line VSL may extend in the first direction DR1. The second voltage line VSL may be disposed above the first gate line GL1 disposed in a (k+1)^{th} row ROWₖ₊₁. The second voltage line VSL may supply the low potential voltage received from the vertical voltage line VVSL to a light emitting element layer EML (see FIG. 8) of the first to third pixels SP1, SP2, and SP3.

The first gate line GL1 may extend in the first direction DR1. The first gate line GL1 may be disposed above the pixel circuit of the first pixel SP1. A part of the first gate line GL1 may be branched to extend in a direction opposite to the second direction DR2. For example, the first gate line GL1 may include an auxiliary line branched from the right sides of the first to third pixels SP1, SP2, and SP3 and extending in the direction opposite to the second direction DR2. The auxiliary line of the first gate line GL1 may be disposed on the right sides of the pixel circuits of the first to third pixels SP1, SP2, and SP3. The first gate line GL1 may supply the first gate signal received from the gate driver 560 to the pixel circuits of the first to third pixels SP1, SP2, and SP3 through the auxiliary line extending in the direction opposite to the second direction DR2.

The second gate line GL2 may extend in the first direction DR1. The second gate line GL2 may be disposed under the pixel circuit of the third pixel SP3. A part of the second gate line GL2 may be branched to extend in the second direction DR2. For example, the second gate line GL2 may include an auxiliary line branched from the left side of the first voltage line VDL and extending in the second direction DR2. The auxiliary line of the second gate line GL2 may be disposed on the left of the first voltage line VDL. The second gate line GL2 may supply the second gate signal received from the gate driver 560 to the pixel circuits of the first to third pixels SP1, SP2, and SP3 through the auxiliary line extending in the second direction DR2.

The data lines DL may extend in the second direction DR2. The data lines DL may supply a data voltage to the pixel SP. The data lines DL may include first to third data lines DL1, DL2, and DL3.

The second data line DL2 may extend in the second direction DR2. The second data line DL2 may be disposed on the right side of the auxiliary line of the first gate line GL1. The second data line DL2 may supply the data voltage received from the display driver 520 to the pixel circuit of the second pixel SP2.

The third data line DL3 may extend in the second direction DR2. The third data line DL3 may be disposed on the right side of the second data line DL2. The third data line DL3 may supply the data voltage received from the display driver 520 to the pixel circuit of the third pixel SP3. The first data line DL1 may extend in the second direction DR2. The first data line DL1 may be disposed on the right side of the third data line DL3. The first data line DL1 may supply the data voltage received from the display driver 520 to the pixel circuit of the first pixel SP1.

In the drawings, the second data line DL2, the third data line DL3, and the first data line DL1 are shown to be arranged in this order in the first direction DR1, but the present disclosure is not limited thereto. The order of the first to third data lines DL1, DL2, and DL3 may be changed in various ways in the first direction DR1.

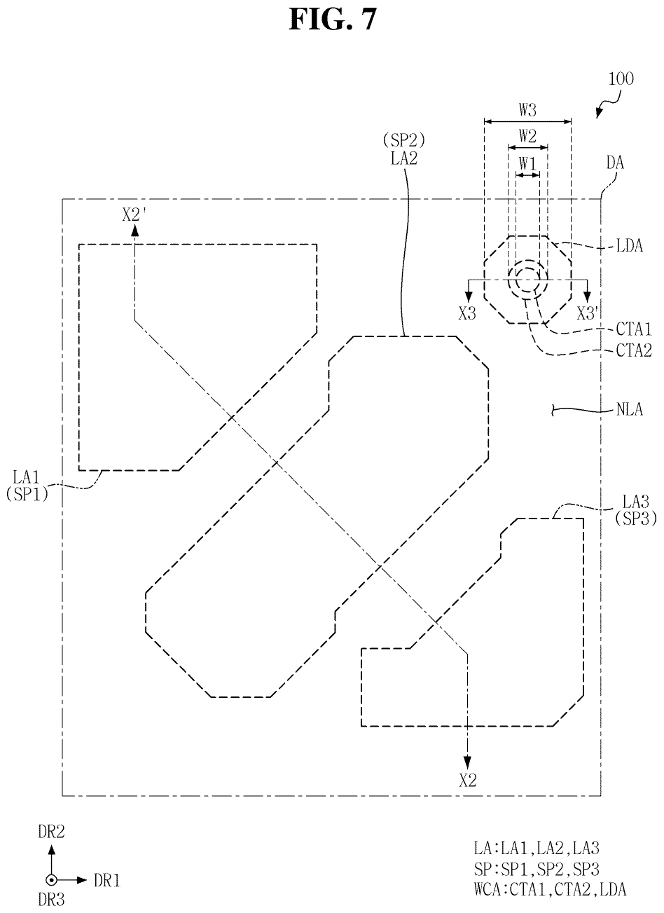

FIG. 7 is a plan view schematically illustrating a part of a display area DA of a display substrate 100 according to an embodiment.

Referring to FIG. 7 in addition to FIGS. 1 to 3, a plurality of emission areas LA and a non-emission area NLA may be defined in the display area DA of the display substrate 100. The plurality of emission areas LA may be regions where light generated by the light emitting element of the display substrate 100 is emitted to the outside of the display substrate 100, and the non-emission area NLA may be a region where light generated by the light emitting element of the display substrate 100 is not emitted to the outside of the display substrate 100. In some embodiments, the plurality of emission areas LA may include a first emission area LA1, a second emission area LA2, and a third emission area LA3.

In some embodiments, the emission area LA and the non-emission area NLA may be defined by a pixel defining film PDL (see FIG. 8). For example, the emission area LA may be a region that overlaps an opening of the pixel defining film PDL (see FIG. 8), and the non-emission area NLA may be a region that does not overlap an opening of the pixel defining film PDL (see FIG. 8).

In an embodiment, the light emitted from the display substrate 100 to the color conversion substrate 200 in the plurality of emission areas LA may be light of a third color. For example, the light of the third color may be blue light, and may have a peak wavelength within a range of about 440 nm to about 480 nm. The peak wavelength may refer to a wavelength at which the intensity of light is maximized within a wavelength range. However, the present disclosure is not limited thereto, and the light emitted from the display substrate 100 to the color conversion substrate 200 in the plurality of emission areas LA may be light in an ultraviolet region.

When the first to third light emission areas LA1, LA2, and LA3 emit light of the same color, the first to third pixels SP1, SP2, and SP3 may express various colors according to color conversion patterns or the like included in the color conversion substrate 200.

In an embodiment, the first to third emission areas LA1, LA2, and LA3 may emit light of different colors. For example, the color of light emitted from the first emission area LA1 may be red, the color of light emitted from the second emission area LA2 may be green, and the color of light emitted from the third emission area LA3 may be blue.

The first emission area LA1, the second emission area LA2, and the third emission area LA3 may constitute the first pixel SP1, the second pixel SP2, and the third pixel SP3, respectively. The first emission area LA1, the second emission area LA2, and the third emission area LA3 may be repeatedly disposed along the first direction DR1 and the second direction DR2 in the entire display area DA. The first emission area LA1, the second emission area LA2, and the third emission area LA3 may constitute one unit color pixel.

In an embodiment, as shown in FIG. 7, the first to third emission areas LA1, LA2, and LA3 may be disposed in a diagonal direction defined by opposite directions of the first direction DR1 and the second direction DR2. For example, in one unit color pixel, the first emission area LA1 may be disposed substantially at an upper left portion in plan view, the second emission area LA2 may be disposed substantially at the center in plan view, and the third emission area LA3 may be disposed substantially at a lower right portion in plan view. However, the arrangement order of the first to third emission areas LA1, LA2, and LA3 is not limited thereto.

In an embodiment, as shown in FIG. 7, the shape of the first emission area LA1 may be a polygon extending in the first direction DR1 and the second direction DR2. In the drawing, the shape of the first emission area LA1 is illustrated as a pentagon, for example. The shape of the second emission area LA2 may be a polygon extending in the diagonal direction defined by the first direction DR1 and the second direction DR2. In the drawing, the shape of the second emission area LA2 is illustrated as a polygon having stepped portions at both ends, for example. The shape of the third emission area LA3 may be a polygon extending in the first direction DR1 and the second direction DR2. In the drawing, the shape of the third emission area LA3 is illustrated as a polygon including portions protruding in the opposite direction of the first direction DR1 and in the second direction DR2. The shape of the first to third emission areas LA1, LA2, and LA3 is not limited thereto.

In an embodiment, as shown in FIG. 7, the widths and shapes of the first to third emission areas LA1, LA2, and LA3 may be different from each other. For example, the first emission area LA1 may have similar widths in the first direction DR1 and the second direction DR2. The second emission area LA2 may have a large width in the diagonal direction defined by the first direction DR1 and the second direction DR2, and may have a small width in the diagonal direction defined by the opposite directions of the first direction DR1 and the second direction DR2. Accordingly, the second emission area LA2 may have a substantially polygonal shape elongated in the diagonal direction defined by the first direction DR1 and the second direction DR2. The third emission area LA3 may have similar widths in the first direction DR1 and the second direction DR2.

The non-emission area NLA may be positioned around the emission area LA of the display substrate 100 in the display area DA. The non-emission area NLA may be positioned not only around the emission area LA, but also between the first emission area LA1 and the second emission area LA2, between the second emission area LA2 and the third emission area LA3, and between the third emission area LA3 and the first emission area LA1.

The light emitted from the emission area LA of the display substrate 100 may be provided to the outside of the display device 10 while passing through the light transmitting area of the color conversion substrate 200.

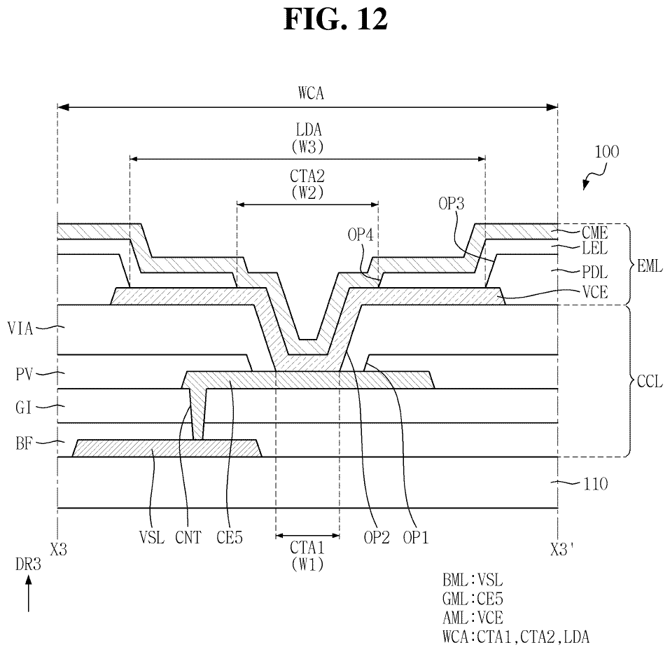

The non-emission area NLA located within the display area DA may include a wiring contact area WCA. The wiring contact area WCA may be an area where an electrode of the light emitting element layer EML (see FIG. 8) and a wiring of a circuit layer CCL (see FIG. 8) are connected to and in contact with each other. For example, the wiring contact area WCA may include openings for connecting the electrode of the light emitting element layer EML (see FIG. 8) to the wiring of the circuit layer CCL (see FIG. 8). In some embodiments, the wiring contact area WCA may include a first contact area CTA1, a second contact area CTA2, and a laser drilling margin area LDA. The wiring contact area WCA will be described later with reference to FIG. 12 and the like.

FIG. 8 is a cross-sectional view taken along line X2-X2′ of FIG. 7 according to an embodiment.

Referring to FIG. 8 in addition to FIG. 7, the display device 10 may include the display substrate 100, the color conversion substrate 200 facing the display substrate 100, and the filler 300 for bonding them.

The display substrate 100 may include a first substrate 110, the circuit layer CCL, the light emitting element layer EML, and an encapsulation structure 170.

The first substrate 110 may include a transparent material. For example, the first substrate 110 may include a transparent insulating material such as glass, quartz, or the like. The first substrate 110 may be a rigid substrate. However, the first substrate 110 is not limited thereto, and may include plastic such as polyimide or the like, and may have a flexible property such that it can be twisted, bent, folded, or rolled.

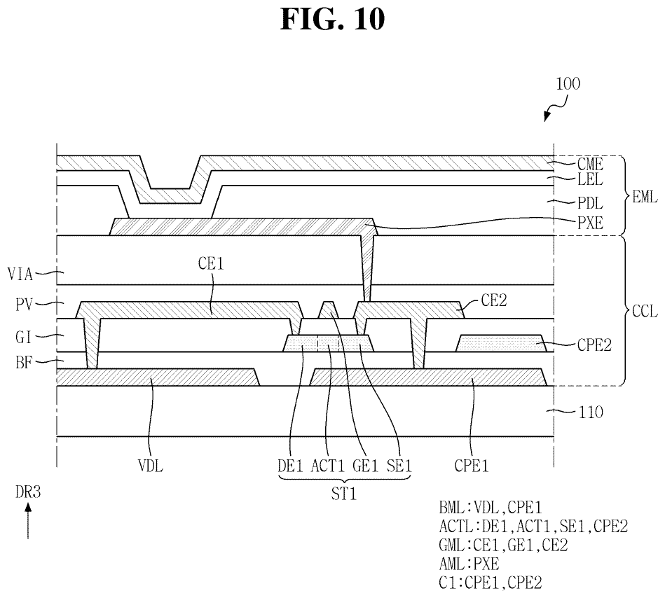

The circuit layer CCL (for example, a thin film transistor layer) may be disposed on the first substrate 110. A description of the circuit layer CCL will be given later with reference to FIG. 10 and the like.

The light emitting element layer EML may be disposed on the circuit layer CCL. The light emitting element layer EML may include a pixel electrode PXE (sometimes called a first electrode PXE), the pixel defining film PDL, a light emitting layer LEL, and a common electrode CME.

The pixel electrode PXE may be a first electrode (e.g., an anode electrode) of a light emitting diode. The pixel electrode PXE may have a stacked structure formed by stacking a material layer having a high work function, such as indium tin oxide (ITO), indium zinc oxide (IZO), zinc oxide (ZnO) and indium oxide (In₂O₃), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), or a mixture thereof. The material layer having a high work function may be disposed above the reflective material layer and disposed closer to the light emitting layer LEL. The pixel electrode PXE may have a multilayer structure such as ITO/Mg, ITO/MgF, ITO/Ag and ITO/Ag/ITO, but is not limited thereto.

The pixel electrode PXE may include a first pixel electrode PXR, a second pixel electrode PXG, and a third pixel electrode PXB. The first pixel electrode PXR may be disposed to overlap the first emission area LA1. The second pixel electrode PXG may be disposed to overlap the second emission area LA2. The third pixel electrode PXB may be disposed to overlap the third emission area LA3.

The pixel defining film PDL may be disposed along the boundary of the pixel SP on one surface of the first substrate 110. The pixel defining film PDL may be disposed on the pixel electrode PXE and may include an opening to extend to and expose the pixel electrode PXE. The emission area LA and the non-emission area NLA may be distinguished by the pixel defining film PDL and the opening thereof.

The pixel defining film PDL may include an organic insulating material such as acrylic resin, epoxy resin, phenolic resin, polyamide resin, polyimide resin, unsaturated polyester resin, polyphenylene resin, polyphenylenesulfide resin or benzocyclobutene (BCB). The pixel defining film PDL may include an inorganic material.

The light emitting layer LEL may be disposed on the pixel electrode PXE exposed by the pixel defining film PDL. The light emitting layer LEL may be in contact with not only the pixel electrode PXE, but also the side surface and the top surface of the pixel defining film PDL. The light emitting layer LEL may be connected across the emission area LA and the pixel SP. The light emitting layer LEL may be disposed over the entire surface across the emission area LA and the pixel SP. Accordingly, the wavelength of light emitted from the light emitting layer LEL may be the same for each of the emission areas LA1, LA2, and LA3. For example, the light emitting layer LEL of each of the emission areas LA1, LA2, and LA3 may emit blue light or ultraviolet rays, and the color conversion substrate 200 which will be described later may include a wavelength conversion layer WCL, thereby displaying a color for each pixel SP.

In an embodiment, the light emitting layers LEL may be spaced apart from each other for each of the emission areas LA1, LA2, and LA3 distinguished by the pixel defining film PDL. In this case, the wavelength of light emitted from each light emitting layer LEL may be the same for each of the emission areas LA1, LA2, and LA3.

In an embodiment in which the display device 10 is an organic light emitting display, the light emitting layer LEL may include an organic layer containing an organic material. The organic layer may have an organic light emitting layer, and in some cases, may further have at least one of a hole injection layer, a hole transport layer, an electron transport layer, or an electron injection layer as an auxiliary layer for light emission. In an embodiment, when the display device 10 is a micro LED display, a nano LED display or the like, the light emitting layer LEL may include an inorganic material such as an inorganic semiconductor.

In some embodiments, the light emitting layer LEL may have a tandem structure in which a plurality of organic light emitting layers are superposed in the thickness direction and a charge generation layer is disposed between the organic light emitting layers. The respective organic light emitting layers superposed may emit light of the same wavelength, or may emit light of different wavelengths. At least some of the light emitting layers LEL of each pixel SP may be separated from or connected to the same layer of the neighboring pixel SP by the pixel defining film PDL. The common electrode CME may be arranged on the light emitting layer LEL. The common electrode CME may be connected across the emission area LA and the pixel SP. The common electrode CME may be a full surface electrode disposed over the entire surface across the emission area LA and the pixel SP. The common electrode CME (sometime called a third metal layer CME) may be or include a second electrode (e.g., a cathode electrode) of a light emitting diode. The common electrode CME may include a material layer having a low work function, such as Li, Ca, LiF/Ca, LiF/Al, Al, Mg, Ag, Pt, Pd, Ni, Au Nd, Ir, Cr, BaF, Ba or a compound or mixture thereof (e.g., a mixture of Ag and Mg). The common electrode CME may further include a transparent metal oxide layer disposed on the material layer having a low work function.

The pixel electrode PXE, the light emitting layer LEL, and the common electrode CME may constitute a light emitting element (e.g., an OLED). Light emitted from the light emitting layer LEL may be emitted upward through the common electrode CME.

The encapsulation structure 170 may be disposed on the common electrode CME. The encapsulation structure 170 may include at least a thin film encapsulation layer. For example, the encapsulation structure 170 may include a first encapsulation inorganic film 171, an encapsulation organic film 172, and a second encapsulation inorganic film 173.

The first encapsulation inorganic film 171 may be disposed on the light emitting element layer EML. The first encapsulation inorganic film 171 may include silicon nitride (SiNx), silicon oxide (SiOx), silicon oxynitride (SiOxNy), or the like.

The encapsulation organic film 172 may be disposed on the first encapsulation inorganic film 171. The encapsulation organic film 172 may include an organic insulating material selected from the group consisting of acrylic resin, epoxy resin, phenolic resin, polyamide resin, polyimide resin, unsaturated polyester resin, polyphenylene ether resin, polyphenylenesulfide resin and benzocyclobutene (BCB).

The second encapsulation inorganic film 173 may be disposed on the encapsulation organic film 172. The second encapsulation inorganic film 173 may include the same material as the first encapsulation inorganic film 171 described above. For example, the second encapsulation inorganic film 173 may include silicon nitride (SiNx), silicon oxide (SiOx), silicon oxynitride (SiOxNy), or the like.

In some embodiments, some layers of the encapsulation structure 170 or the entire encapsulation structure 170 may be omitted. When the encapsulation structure 170 is omitted, the filler 300, the sealing portion 400, and the color conversion substrate 200 may be directly disposed on the light emitting element layer EML, and the filler 300, the sealing portion 400, and the color conversion substrate 200 may directly perform an encapsulation function.

The color conversion substrate 200 may be disposed to face the display substrate 100 on the encapsulation structure 170. The color conversion substrate 200 may include a second substrate 210, a light blocking member BM, a color filter layer CFL, a first capping layer 220, a partition wall PTL, the wavelength conversion layer WCL, a light transmitting layer TPL, and a second capping layer 230.

The second substrate 210 may include a transparent material. The second substrate 210 may include a transparent insulating material such as glass, quartz, or the like. The second substrate 210 may be a rigid substrate. However, the second substrate 210 is not limited thereto. The second substrate 210 may include plastic such as polyimide or the like, and may have a flexible property such that it can be twisted, bent, folded, or rolled.

The second substrate 210 may be the same substrate as the first substrate 110, but may have a different material, thickness, transmittance and the like. For example, the second substrate 210 may have a higher transmittance than the first substrate 110. The second substrate 210 may be thicker or thinner than the first substrate 110.

The light blocking member BM may be disposed along the boundary of the pixel SP on one surface of the second substrate 210 that faces the first substrate 110. The light blocking member BM may overlap the pixel defining film PDL of the display substrate 100 and may be positioned in the non-emission area NLA. The light blocking member BM may include an opening to extend to and expose one surface of the second substrate 210 overlapping the emission area LA. The light blocking member BM may be formed in a grid shape in plan view.

The light blocking member BM may include an organic material. The light blocking member BM may reduce color distortion due to external light reflection by absorbing the external light. Further, the light blocking member BM may serve to prevent light which is emitted from the light emitting layer LEL from entering the adjacent pixels SP.

In an embodiment, the light blocking member BM may absorb all visible wavelengths. The light blocking member BM may include a light absorbing material. For example, the light blocking member BM may be formed of a material used as a black matrix of the display device 10.

In an embodiment, the light blocking member BM may absorb light of specific wavelengths among visible wavelengths and transmit light of other wavelengths. For example, the light blocking member BM may include the same material as the color filter layer CFL. Specifically, the light blocking member BM may be made of the same material as a blue color filter layer. In some embodiments, the light blocking member BM may be integrally formed with the blue color filter layer. In an embodiment, the light blocking member BM may be omitted.

The color filter layer CFL may be disposed on one surface of the second substrate 210 on which the light blocking member BM is disposed. The color filter layer CFL may be provided on the surface of the second substrate 210 which is exposed through the opening of the light blocking member BM. Further, each color filter layer CFL may be partially disposed on the adjacent light blocking member BM.

The color filter layer CFL may include a first color filter layer CFL1 disposed in the first pixel SP1, a second color filter layer CFL2 disposed in the second pixel SP2, and a third color filter layer CFL3 disposed in the third pixel SP3. Each of the color filter layers CFL may include a colorant such as a dye or a pigment that absorbs wavelengths other than the corresponding color wavelength. The first color filter layer CFL1 may be a red color filter layer, the second color filter layer CFL2 may be a green color filter layer, and the third color filter layer CFL3 may be a blue color filter layer. In the drawing, the neighboring color filter layers CFL are disposed to be spaced apart from each other on the light blocking member BM, but the neighboring color filter layers CFL may partially overlap each other on the light blocking member BM.

The first capping layer 220 may be disposed on the color filter layer CFL. The first capping layer 220 may prevent impurities such as moisture or air from permeating from the outside and damaging or contaminating the color filter layers CFL. Further, the first capping layer 220 may prevent the colorants of the color filter layers CFL from being diffused into other components.

The first capping layer 220 may be in direct contact with one surface (bottom surface in FIG. 8) of the color filter layer CFL. The first capping layer 220 may be made of an inorganic material. For example, the first capping layer 220 may include silicon nitride, aluminum nitride, zirconium nitride, titanium nitride, hafnium nitride, tantalum nitride, silicon oxide, aluminum oxide, titanium oxide, tin oxide, silicon oxynitride, or the like.

The partition wall PTL may be disposed on the first capping layer 220. The partition wall PTL may be positioned in the non-emission area NLA. The partition wall PTL may be disposed to overlap the light blocking member BM. The partition wall PTL may include an opening extending to and exposing the color filter layer CFL. The partition wall PTL may include a photosensitive organic material, but the present disclosure is not limited thereto. The partition wall PTL may further include a light blocking material.

The wavelength conversion layer WCL and/or the light transmitting layer TPL may be disposed in the space exposed by the opening of the partition wall PTL. The wavelength conversion layer WCL and the light transmitting layer TPL may be formed by an inkjet process using the partition wall PTL as a bank, but the present disclosure is not limited thereto.

In an embodiment in which the light emitting layer LEL of each pixel SP emits light in a third color, the wavelength conversion layer WCL may include a first wavelength conversion pattern WCL1 disposed in the first pixel SP1 and a second wavelength conversion pattern WCL2 disposed in the second pixel SP2. The light transmitting layer TPL may be disposed in the third pixel SP3.

The first wavelength conversion pattern WCL1 may include a first base resin BRS1 and a first wavelength conversion material WCP1 provided in the first base resin BRS1. The second wavelength conversion pattern WCL2 may include a second base resin BRS2 and a second wavelength conversion material WCP2 provided in the second base resin BRS2. The light transmitting layer TPL may include a third base resin BRS3 and a scatterer SCP provided in the third base resin BRS3.

The first to third base resins BRS1, BRS2, and BRS3 may include a light transmitting organic material. For example, the first to third base resins BRS1, BRS2, and BRS3 may include an epoxy resin, an acrylic resin, a cardo resin, an imide resin, or the like. The first to third base resins BRS1, BRS2 and BRS3 may be formed of the same material, but the present disclosure is not limited thereto.

The scatterer SCP may be a metal oxide particle or an organic particle. Examples of the metal oxide may include titanium oxide (TiO₂), zirconium oxide (ZrO₂), aluminum oxide (Al₂O₃), indium oxide (In₂O₃), zinc oxide (ZnO), tin oxide (SnO₂), and the like. Examples of a material of the organic particles may include acrylic resin and urethane resin, and the like.

The first wavelength conversion material WCP1 may convert the third color into the first color, and the second wavelength conversion material WCP2 may convert the third color into the second color. The first wavelength conversion material WCP1 and the second wavelength conversion material WCP2 may be quantum dots, quantum bars, phosphors or the like. Examples of the quantum dot may include group IV nanocrystal, group II-VI compound nanocrystal, group III-V compound nanocrystal, group IV-VI nanocrystal, and a combination thereof. The first wavelength conversion pattern WCL1 and the second wavelength conversion pattern WCL2 may further include a scatterer SCP for increasing wavelength conversion efficiency.

The light transmitting layer TPL disposed in the third pixel SP3 may transmit light of a third color emitted from the light emitting layer LEL while maintaining the wavelength thereof. The scatterer SCP of the light transmitting layer TPL may serve to control an emission path of the light emitted through the light transmitting layer TPL. The light transmitting layer TPL may not include a wavelength conversion material.

The second capping layer 230 may be disposed on the wavelength conversion layer WCL, the light transmitting layer TPL, and the partition wall PTL. The second capping layer 230 may be formed of an inorganic material. The second capping layer 230 may include a material selected from the above-mentioned materials of the first capping layer 220. The first capping layer 220 and the second capping layer 230 may be formed of the same material, but the present disclosure is not limited thereto.

The filler 300 may be disposed between the display substrate 100 and the color conversion substrate 200. The filler 300 may fill a space between the display substrate 100 and the color conversion substrate 200, and may serve to bond them to each other. The filler 300 may be disposed between the encapsulation structure 170 of the display substrate 100 and the second capping layer 230 of the color conversion substrate 200. The filler 300 may be formed of a Si-based organic material, an epoxy-based organic material, or the like, but is not limited thereto.

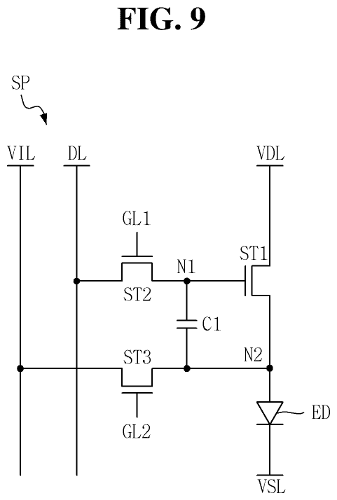

FIG. 9 is an equivalent circuit diagram of a pixel SP according to an embodiment.

Referring to FIG. 9, each of the pixels SP may be connected to the first voltage line VDL, the data line DL, the initialization voltage line VIL, the first gate line GL1, the second gate line GL2, and the second voltage line VSL.

Each of the pixels SP may include a pixel circuit and a light emitting element ED. In an embodiment, as shown in the drawing, the pixel circuit of each pixel SP may have a 3T1C structure including three transistors and one capacitor. For example, the pixel circuit of each pixel SP may include first to third transistors ST1, ST2, and ST3 and a capacitor C1. However, the present disclosure is not limited thereto, and the number of the transistors and the capacitors of each pixel circuit may be varied in various ways. Below, for simplicity of description, the following description will be provided for the 3T1C structure as an example, but the present disclosure is not limited thereto and various other modified structures such as 2T1C structure, 7T1C structure, 6TIC structure, and 17T3C may be adopted.

The first transistor ST1 may include a gate electrode, a drain electrode, and a source electrode. The gate electrode of the first transistor ST1 may be connected to a first node N1, the drain electrode thereof may be connected to the first voltage line VDL, and the source electrode thereof may be connected to a second node N2. The first transistor ST1 may control a drain-source current (or driving current) based on a data voltage applied to the gate electrode. The first transistor ST1 may be a driving transistor for driving the light emitting element ED.

The light emitting element ED may emit light by receiving a driving current. The light emission amount or the luminance of the light emitting element ED may be proportional to the magnitude of the driving current. The light emitting element ED may be an organic light emitting diode (OLED) having an organic light emitting layer, a quantum dot light emitting diode (LED) including a quantum dot light emitting layer, a micro LED, or an inorganic LED having an inorganic semiconductor.

The first electrode (e.g., pixel electrode) of the light emitting element ED may be connected to the second node N2, and the second electrode of the light emitting element ED may be connected to the second voltage line VSL. The first electrode of the light emitting element ED may be connected to the source electrode of the first transistor ST1, the drain electrode of the third transistor ST3, and the first capacitor electrode of the capacitor C1, through the second node N2.

The second transistor ST2 may be turned on by the first gate signal of the first gate line GL1 to electrically connect the data line DL to the first node N1 which is the gate electrode of the first transistor ST1. The second transistor ST2 may be turned on based on the first gate signal to supply the data voltage to the first node N1. The gate electrode of the second transistor ST2 may be connected to the first gate line GL1, the drain electrode thereof may be connected to the data line DL, and the source electrode thereof may be connected to the first node N1. The source electrode of the second transistor ST2 may be connected to the gate electrode of the first transistor ST1 and a second capacitor electrode of the capacitor C1 through the first node N1. The second transistor ST2 may be a switching transistor for controlling the current flowing through the first transistor ST1 and the light emitting element ED.

The third transistor ST3 may be turned on by the second gate signal of the second gate line GL2 to electrically connect the initialization voltage line VIL to the second node N2 which is the source electrode of the first transistor ST1. The third transistor ST3 may be turned on according to the second gate signal to supply the initialization voltage to the second node N2. The third transistor ST3 may be turned on according to the second gate signal to supply the sensing signal to the initialization voltage line VIL. The gate electrode of the third transistor ST3 may be connected to the second gate line GL2, the drain electrode thereof may be connected to the second node N2, and the source electrode thereof may be connected to the initialization voltage line VIL. The drain electrode of the third transistor ST3 may be connected to the source electrode of the first transistor ST1, the first capacitor electrode of the capacitor C1, and the first electrode of the light emitting element ED, through the second node N2. The third transistor ST3 may be a switching transistor for controlling the current flowing through the first transistor ST1 and the light emitting element ED.

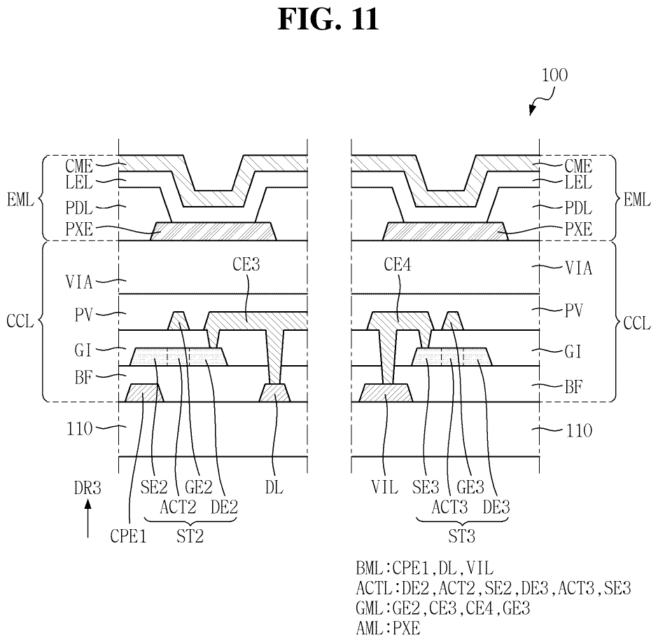

FIG. 10 is a cross-sectional view showing an example of a first transistor ST1 of a circuit layer CCL according to an embodiment. FIG. 11 is a cross-sectional view showing an example of a second transistor ST2 and a third transistor ST3 of a circuit layer CCL according to an embodiment.

Referring to FIGS. 10 to 11 in addition to FIG. 9, the display substrate 100 may include the first substrate 110, the circuit layer CCL, and the light emitting element layer EML.

Since the description of the first substrate 110 has been given above with reference to FIG. 8, it will be omitted.

The circuit layer CCL may be disposed on the first substrate 110. The circuit layer CCL (e.g., a thin film transistor layer) may include a lower conductive layer BML, a buffer film BF, an active layer ACTL, a gate insulating film GI, a gate conductive layer GML (sometimes called a first metal layer GML), a passivation film PV (sometimes called a second insulating film PV), and a via film VIA (sometimes called a first insulating film VIA). The circuit layer CCL may include the first to third transistors ST1, ST2, and ST3 and the capacitor C1.

The lower conductive layer BML may be disposed on the first substrate 110. The lower conductive layer BML may include a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

In an embodiment, the lower conductive layer BML may include the initialization voltage line VIL, the data line DL, the first voltage line VDL, the second voltage line VSL, and a first capacitor electrode CPE1 of the capacitor C1.

The buffer film BF may be disposed on the lower conductive layer BML. The buffer film BF may include an inorganic material such as a silicon nitride layer, a silicon oxynitride layer, a silicon oxide layer, a titanium oxide layer and an aluminum oxide layer. In an embodiment, the buffer film BF may include a multilayer in which a plurality of layers selected from a silicon nitride layer, a silicon oxynitride layer, a silicon oxide layer, a titanium oxide layer and an aluminum oxide layer are alternately stacked.

The active layer ACTL may be disposed on the buffer film BF. The active layer ACTL may include polycrystalline silicon, monocrystalline silicon, low-temperature polycrystalline silicon, amorphous silicon, or an oxide semiconductor material.

In an embodiment, the active layer ACTL may include a first active region ACT1, a first drain electrode DE1, and a first source electrode SE1 of the first transistor ST1; a second active region ACT2, a second drain electrode DE2, and a second source electrode SE2 of the second transistor ST2; a third active region ACT3, a third drain electrode DE3, and a third source electrode SE3 of the third transistor ST3; and a second capacitor electrode CPE2 of the capacitor C1.

The gate insulating film GI may be disposed on the active layer ACTL. The gate insulating film GI may include an inorganic film, for example, a silicon nitride layer, a silicon oxynitride layer, a silicon oxide layer, a titanium oxide layer, or an aluminum oxide layer. The gate conductive layer GML may be disposed on the gate insulating film GI. The gate conductive layer GML may include a single layer or multiple layers made of any one of molybdenum (Mo), aluminum (Al), chromium (Cr), gold (Au), titanium (Ti), nickel (Ni), neodymium (Nd) and copper (Cu) or an alloy thereof.

In an embodiment, the gate conductive layer GML, sometimes called a first metal layer GML, may include the first gate line GL1, the second gate line GL2, a first gate electrode GE1 of the first transistor ST1, a second gate electrode GE2 of the second transistor ST2, a third gate electrode GE3 of the third transistor ST3, and connection electrodes CE1, CE2, CE3, and CE4.

The passivation film PV may be disposed on the gate conductive layer GML. The passivation film PV may include an inorganic film, for example, a silicon nitride layer, a silicon oxynitride layer, a silicon oxide layer, a titanium oxide layer, or an aluminum oxide layer.

The via film VIA may be disposed on the passivation film PV. The via film VIA may include an organic film such as an acryl resin, an epoxy resin, a phenolic resin, a polyamide resin, a polyimide resin, or the like.

The circuit layer CCL may include the first to third transistors ST1, ST2, and ST3 and the capacitor C1.

The first transistor ST1 may include the first active region ACT1, the first gate electrode GE1, the first drain electrode DE1, and the first source electrode SE1.

The first active region ACT1 may be disposed in the active layer ACTL. The first active region ACT1 may overlap the first gate electrode GE1 in the third direction DR3. The first active region ACT1 may be a region where the active layer ACTL is not made conductive in an area overlapping the first gate electrode GE1.

The first gate electrode GE1 may be disposed in the gate conductive layer GML. As shown in FIGS. 9 and 10, the first gate electrode GE1 may be connected to the second source electrode SE2 of the second transistor ST2 and the second capacitor electrode CPE2 of the capacitor C1 through the first node N1.

In the drawing, the first transistor ST1 is shown as having a top gate structure in which the first gate electrode GE1 is disposed on top of the first active region ACT1, but the structure of the first transistor ST1 is not limited thereto. As an example, the first transistor ST1 may have a bottom gate structure in which the first gate electrode GE1 is disposed below the first active region ACT1. As another example, the first transistor ST1 may have a double gate structure in which the first gate electrode GE1 is disposed both above and below the first active region ACT1.

The first drain electrode DE1 and the first source electrode SE1 may be formed by heat treating the active layer ACTL to make it conductive. The first drain electrode DE1 and the first source electrode SE1 may be made conductive as a P-type semiconductor or an N-type semiconductor, but are not limited thereto.

As shown in FIG. 9, the first drain electrode DE1 may be electrically connected to the first voltage line VDL. For example, as shown in FIG. 10, the first drain electrode DE1 may be connected to the first voltage line VDL through the first connection electrode CE1. Accordingly, the first drain electrode DE1 may receive the driving voltage from the first voltage line VDL.

As shown in FIGS. 9 and 10, the first source electrode SE1 may be connected to the light emitting element ED through the second node N2. For example, as shown in FIG. 10, the first source electrode SE1 may be connected to the pixel electrode PXE through the second connection electrode CE2. Accordingly, the first source electrode SE1 may supply a driving current to the light emitting element ED.

As shown in FIGS. 9 and 10, the first source electrode SE1 may be connected to the capacitor C1 through the second node N2. For example, as shown in FIG. 10, the first source electrode SE1 may be connected to the first capacitor electrode CPE1 of the capacitor C1 through the second connection electrode CE2.

The second transistor ST2 may include the second active region ACT2, the second gate electrode GE2, the second drain electrode DE2, and the second source electrode SE2.

The second active region ACT2 may be disposed in the active layer ACTL. The second active region ACT2 may overlap the second gate electrode GE2 in the third direction DR3. The second active region ACT2 may be a region where the active layer ACTL is not made conductive in an area overlapping the second gate electrode GE2.

The second gate electrode GE2 may be disposed in the gate conductive layer GML. As shown in FIGS. 9 and 11, the second gate electrode GE2 may be connected to the first gate line GL1. Accordingly, the second gate electrode GE2 may receive the first gate signal from the first gate line GL1.

In the drawing, the second transistor ST2 is shown as having a top gate structure in which the second gate electrode GE2 is disposed on top of the second active region ACT2, but the structure of the second transistor ST2 is not limited thereto. As an example, the second transistor ST2 may have a bottom gate structure in which the second gate electrode GE2 is disposed below the second active region ACT2. As another example, the second transistor ST2 may have a double gate structure in which the second gate electrode GE2 is disposed both above and below the second active region ACT2.

The second drain electrode DE2 and the second source electrode SE2 may be formed by heat treating the active layer ACTL to make it conductive. The second drain electrode DE2 and the second source electrode SE2 may be made conductive as a P-type semiconductor or an N-type semiconductor, but are not limited thereto.

As shown in FIGS. 9 and 11, the second drain electrode DE2 may be electrically connected to the data line DL. For example, as shown in FIG. 11, the second drain electrode DE2 may be connected to the data line DL through the third connection electrode CE3. Accordingly, the second drain electrode DE2 may receive the data voltage from the data line DL.

As shown in FIGS. 9 and 11, the second source electrode SE2 may be connected to the first gate electrode GE1 of the first transistor ST1 through the first node N1. Accordingly, the second source electrode SE2 may supply the data voltage to the first gate electrode GE1 of the first transistor ST1 through the first node N1. The first transistor ST1 may control the driving current based on the data voltage received from the second source electrode SE2.

As shown in FIGS. 9 and 11, the second source electrode SE2 may be connected to the capacitor C1 through the first node N1. For example, although not shown in the drawing, the second source electrode SE2 may be connected to the second capacitor electrode CPE2 of the capacitor C1 through a separate connection electrode disposed in the gate conductive layer GML.

The third transistor ST3 may include the third active region ACT3, the third gate electrode GE3, the third drain electrode DE3, and the third source electrode SE3.

The third active region ACT3 may be disposed in the active layer ACTL. The third active region ACT3 may overlap the third gate electrode GE3 in the third direction DR3. The third active region ACT3 may be a region where the active layer ACTL is not made conductive in an area overlapping the third gate electrode GE3.

The third gate electrode GE3 may be disposed in the gate conductive layer GML. The third gate electrode GE3 may be connected to the second gate line GL2 as shown in FIG. 9. Accordingly, the third gate electrode GE3 may receive the second gate signal from the second gate line GL2.

In the drawing, the third transistor ST3 is shown as having a top gate structure in which the third gate electrode GE3 is disposed on top of the third active region ACT3, but the structure of the third transistor ST3 is not limited thereto. As an example, the third transistor ST3 may have a bottom gate structure in which the third gate electrode GE3 is disposed below the third active region ACT3. As another example, the third transistor ST3 may have a double gate structure in which the third gate electrode GE3 is disposed both above and below the third active region ACT3.

The third drain electrode DE3 and the third source electrode SE3 may be formed by heat treating the active layer ACTL to make it conductive. The third drain electrode DE3 and the third source electrode SE3 may be made conductive as a P-type semiconductor or an N-type semiconductor, but are not limited thereto.

As shown in FIGS. 9 and 11, the third drain electrode DE3 may be electrically connected

to the first source electrode SE1 of the first transistor ST1. For example, although not shown in the drawing, the third drain electrode DE3 may be connected to the first source electrode SE1 of the first transistor ST1 through a separate connection electrode disposed in the gate conductive layer GML.

The third drain electrode DE3 may be connected to the capacitor C1, as shown in FIG. 9. For example, although not shown in the drawing, the third drain electrode DE3 may be connected to the first capacitor electrode CPE1 of the capacitor C1 through a separate connection electrode disposed in the gate conductive layer GML.

As shown in FIGS. 9 and 11, the third source electrode SE3 may be connected to the initialization voltage line VIL. For example, as shown in FIG. 11, the third source electrode SE3 may be connected to the initialization voltage line VIL through the fourth connection electrode CE4. Accordingly, the third source electrode SE3 may receive an initialization voltage from the initialization voltage line VIL, and the third source electrode SE3 may supply a sensing signal to the initialization voltage line VIL.

The capacitor C1 may include a first capacitor electrode CPE1 and a second capacitor electrode CPE2.

The first capacitor electrode CPE1 may be disposed in the lower conductive layer BML. The first capacitor electrode CPE1 may be connected to the first source electrode SE1 of the first transistor ST1 through the second connection electrode CE2. The first capacitor electrode CPE1 may be connected to the third drain electrode DE3 of the third transistor ST3 through a separate connection electrode disposed in the gate conductive layer GML.

The second capacitor electrode CPE2 may be disposed in the active layer ACTL. The second capacitor electrode CPE2 may be connected to the first gate electrode GE1 of the first transistor ST1 through a separate connection electrode disposed in the gate conductive layer GML. The second capacitor electrode CPE2 may be connected to the second source electrode SE2 of the second transistor ST2 through a separate connection electrode disposed in the gate conductive layer GML.

The light emitting element layer EML may include an anode conductive layer AML (sometimes called a second metal layer AML), the pixel defining film PDL, the light emitting layer LEL, and the common electrode CME.

Descriptions of the pixel defining film PDL, the light emitting layer LEL, and the common electrode CME have been made above with reference to FIG. 8 and will therefore be omitted.

The anode conductive layer AML may be disposed on the circuit layer CCL. For example, the anode conductive layer AML may be disposed on the via film VIA. In an embodiment, the anode conductive layer AML may include the pixel electrode PXE.

The anode conductive layer AML may have a stacked structure formed by stacking a material layer having a high work function, such as indium tin oxide (ITO), indium zinc oxide (IZO), zinc oxide (ZnO) and indium oxide (In₂O₃), and a reflective material layer such as silver (Ag), magnesium (Mg), aluminum (Al), platinum (Pt), lead (Pb), gold (Au), nickel (Ni), neodymium (Nd), iridium (Ir), chromium (Cr), lithium (Li), calcium (Ca), or a mixture thereof. The material layer having a high work function may be disposed above the reflective material layer and disposed closer to the light emitting layer LEL. The pixel electrode PXE may have a multilayer structure such as ITO/Mg, ITO/MgF, ITO/Ag and ITO/Ag/ITO, but is not limited thereto.

In the display device 10 according to the present embodiment, by minimizing the number of layers of the circuit layer CCL, the number of masks required for the patterning of the respective layers is reduced, so that process efficiency can be improved.

As an example, by disposing the wires such as the data line DL, the initialization voltage line VIL, the first voltage line VDL, and the second voltage line VSL in the lower conductive layer BML while disposing the wires such as the gate line GL, the horizontal voltage line HVDL, and the second voltage line VSL in the gate conductive layer GML, a separate layer for the disposition of the wires is not added, so that the number of layers can be minimized.

As another example, by disposing the first capacitor electrode CPE1 in the lower conductive layer BML and the second capacitor electrode CPE2 in the active layer ACTL, a separate layer for the disposition of the capacitor C1 is not added, so that the number of layers can be minimized.

As still another example, by disposing the connection electrodes for connecting the lower conductive layer BML, the active layer ACTL, and the gate conductive layer GML in the gate conductive layer GML, a separate layer for the disposition of the connection electrodes is not added, so that the number of layers can be minimized.

In the display device 10 according to the present embodiment, as the number of layers of the circuit layer CCL is minimized, the distance between the light emitting element layer EML and the lower conductive layer BML may be reduced in the third direction DR3. Accordingly, the distance between the wires, such as the data line DL, the initialization voltage line VIL, the first voltage line VDL, and the second voltage line VSL, and the electrodes of the light emitting element layer EML, such as the pixel electrode PXE and the common electrode CME, may be reduced. Additionally, the number of the connection electrodes for the connection of the wires and the electrodes may be reduced. Accordingly, a voltage drop (IR-drop) phenomenon in which the voltage provided from the wires to the electrodes drops can be minimized. This will be described later with reference to FIG. 12 and the like.

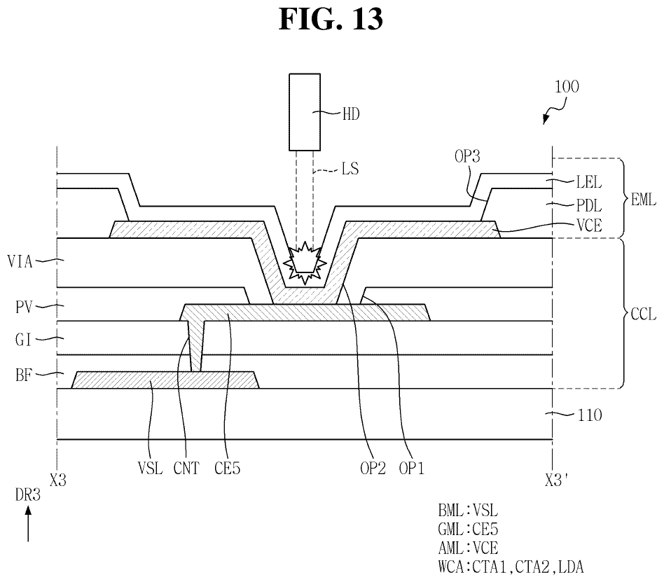

FIG. 12 is a cross-sectional view taken along line X3-X3′ of FIG. 7 according to an embodiment. FIG. 13 is a cross-sectional view showing a process of removing a part of a light emitting layer through a laser drilling process.

Referring to FIGS. 12 and 13 in addition to FIGS. 7 and 9, the lower conductive layer BML may further include a second voltage line VSL. The gate conductive layer GML may further include a fifth connection electrode CE5 (sometimes called a first voltage line CE5). The anode conductive layer AML may further include an auxiliary electrode VCE.

The second voltage line VSL may receive a low potential voltage from the vertical voltage line VVSL (see FIG. 6). The second voltage line VSL may be connected to the fifth connection electrode CE5. The fifth connection electrode CE5 may connect the second voltage line VSL to the auxiliary electrode VCE. The auxiliary electrode VCE may connect the fifth connection electrode CE5 to the common electrode CME. The second voltage line VSL may provide a low potential voltage to the common electrode CME through the fifth connection electrode CE5 and the auxiliary electrode VCE.

The display substrate 100 may include the wiring contact area WCA. The wiring contact area WCA may be a region where the electrode of the light emitting element layer EML and the wire of the circuit layer CCL are connected to and in contact with each other. For example, as shown in FIG. 12, the second voltage line VSL may be connected to and in contact with the common electrode CME in the wiring contact area WCA through the fifth connection electrode CE5 and the auxiliary electrode VCE.

The wiring contact area WCA may include the first contact area CTA1, the second contact area CTA2, and the laser drilling margin area LDA.

The first contact area CTA1 may be a region where the auxiliary electrode VCE is in contact with the second voltage line VSL or a region which is in contact with the connection electrode connecting the second voltage line VSL to the auxiliary electrode VCE. For example, as shown in FIG. 12, when the auxiliary electrode VCE is connected to the second voltage line VSL through the fifth connection electrode CE5, the first contact area CTA1 may be a region where the auxiliary electrode VCE is in direct contact with the fifth connection electrode CE5. As another example, when the auxiliary electrode VCE is directly connected to the second voltage line VSL without the fifth connection electrode CE5, the first contact area CTA1 may be a region where the auxiliary electrode VCE and the second voltage line VSL are in direct contact with each other.

The second contact area CTA2 may be a region where the common electrode CME is in contact with the auxiliary electrode VCE. For example, as shown in FIG. 12, the second contact area CTA2 may be a region where a part of the light emitting layer LEL is removed and the common electrode CME is in direct contact with the auxiliary electrode VCE.

The light emitting layer LEL in the second contact area CTA2 may be removed by a laser drilling process. For example, as shown in FIG. 13, a laser generator HD may irradiate laser LS to a partial region of the light emitting layer LEL. The light emitting layer LEL in the region irradiated with the laser LS may be removed by the energy of the laser LS. In an embodiment, the wavelength of the laser LS may be approximately 300 nm to 400 nm. In an embodiment, the output energy per unit area of the laser LS may be approximately 200 mJ/cm².

The laser drilling margin area LDA may be a region for securing a process margin for the laser LS in the laser drilling process. The laser drilling margin area LDA may include an area where the light emitting layer LEL is in contact with the auxiliary electrode VCE and an area where the light emitting layer LEL is removed. For example, the laser drilling margin area LDA may include an area where the light emitting layer LEL is in contact with the auxiliary electrode VCE and the second contact area CTA2.

The wiring contact area WCA may include openings for connecting the electrode of the light emitting element layer EML to the wire of the circuit layer CCL. For example, the wiring contact area WCA may include openings located in a non-conductive film to connect the second voltage line VSL to the common electrode CME.

In some embodiments, the wiring contact area WCA may include a contact hole CNT, a first opening OP1, a second opening OP2 (sometimes called a first opening OP2), a third opening OP3 (sometimes called a first or second opening OP3), and a fourth opening OP4 (sometimes called a second or third opening OP4).

The contact hole CNT may penetrate the buffer film BF and the gate insulating film GI. The contact hole CNT may extend to and expose at least a part of the top surface of the second voltage line VSL. The second voltage line VSL and the fifth connection electrode CE5 may be connected to each other through the contact hole CNT. The contact hole CNT may be formed through a photolithography process when forming the buffer film BF and the gate insulating film GI. In some embodiments, when the second voltage line VSL is directly connected to the auxiliary electrode VCE without the fifth connection electrode CE5, the contact hole CNT may be omitted.

The first opening OP1 may penetrate the passivation film PV. The first opening OP1 may extend to and expose at least a part of the top surface of the fifth connection electrode CE5. The auxiliary electrode VCE and the fifth connection electrode CE5 may be connected to each other through the first opening OP1. The first opening OP1 may be formed through a photolithography process when forming the passivation film PV.

The second opening OP2 may penetrate the via film VIA. The second opening OP2 may extend to and expose at least a part of the top surface of the fifth connection electrode CE5. The auxiliary electrode VCE and the fifth connection electrode CE5 may be connected to each other through the first opening OP1 and the second opening OP2. The second opening OP2 may be formed through a photolithography process when forming the via film VIA. The first contact area CTA1 where the auxiliary electrode VCE and the fifth connection electrode CE5 are in contact with each other may be formed by the second opening OP2.

In some embodiments, when the second voltage line VSL is directly connected to the auxiliary electrode VCE without the fifth connection electrode CE5, the auxiliary electrode VCE and the second voltage line VSL may be connected to each other through the first opening OP1 and the second opening OP2.

In some embodiments, the width of the first opening OP1 may be larger than the width of the second opening OP2. Accordingly, it is possible to prevent the auxiliary electrode VCE from being in direct contact with the passivation film PV.

The third opening OP3 may penetrate the pixel defining film PDL. The third opening OP3 may extend to and expose at least a part of the top surface of the auxiliary electrode VCE. The common electrode CME and the auxiliary electrode VCE may be connected to each other through the third opening OP3. The third opening OP3 may be formed through a photolithography process when forming the pixel defining film PDL. The laser drilling margin area LDA, where the light emitting layer LEL is in contact with the auxiliary electrode VCE and a part of the light emitting layer LEL is removed, may be formed by the third opening OP3.

The fourth opening OP4 may penetrate the light emitting layer LEL. The fourth opening OP4 may extend to and expose at least a part of the top surface of the auxiliary electrode VCE. The common electrode CME and the auxiliary electrode VCE may be connected to each other through the fourth opening OP4. The fourth opening OP4 may be formed through a laser drilling process. The second contact area CTA2 where the auxiliary electrode VCE is in contact with the fifth connection electrode CE5 may be formed by the fourth opening OP4.

In some embodiments, each of a width W1 of the first contact area CTA1 and a width W2 of the second contact area CTA2 may be smaller than a width W3 of the laser drilling margin area LDA. In the present specification, the width W1 of the first contact area CTA1 may mean the minimum width of the second opening OP2; the width W2 of the second contact area CTA2 may mean the minimum width of the fourth opening OP4; and the width W3 of the laser drilling margin area LDA may mean the minimum width of the third opening OP3.

In an embodiment, the width W3 of the laser drilling margin area LDA may be approximately 20 μm or more. Desirably, the width W3 of the laser drilling margin area LDA may be approximately 30 μm or more. In an embodiment, the width W1 of the first contact area CTA1 and the width W2 of the second contact area CTA2 may be in a range of about 5 μm to about 30 μm.

In some embodiments, each of the first contact area CTA1 and the second contact area CTA2 may overlap the laser drilling margin area LDA in the third direction DR3. For example, each of the second opening OP2 of the via film VIA and the fourth opening OP4 of the light emitting layer LEL may overlap the third opening OP3 of the pixel defining film PDL in the third direction DR3. The entire first contact area CTA1 and the entire second contact area CTA2 may each be located within an area that overlaps the laser drilling margin area LDA.

Accordingly, it is possible to secure the maximum width W3 of the laser drilling margin area LDA within the wiring contact area WCA of the same width. Therefore, a laser drilling process margin can be secured even in a high-resolution panel.

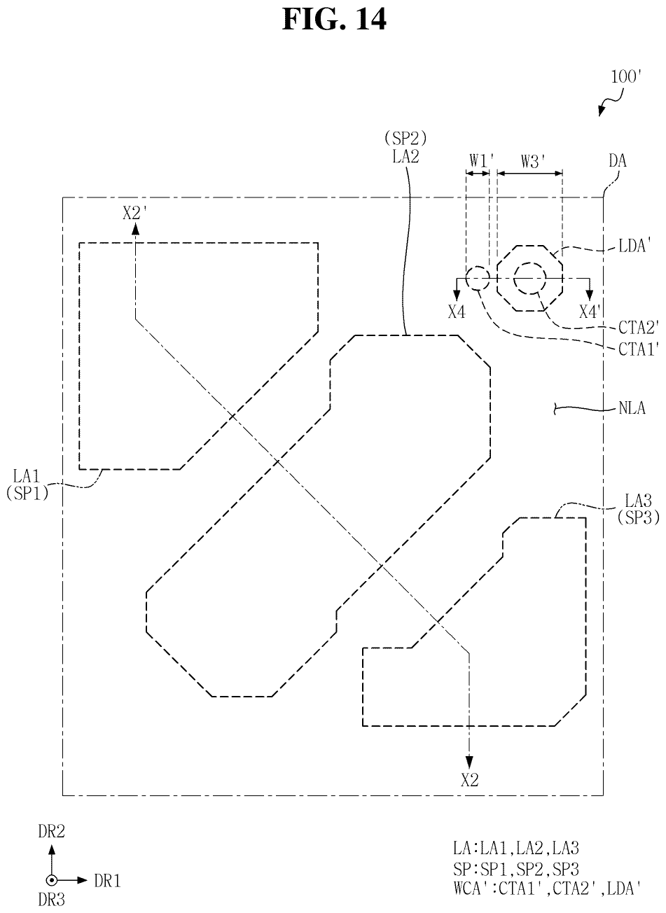

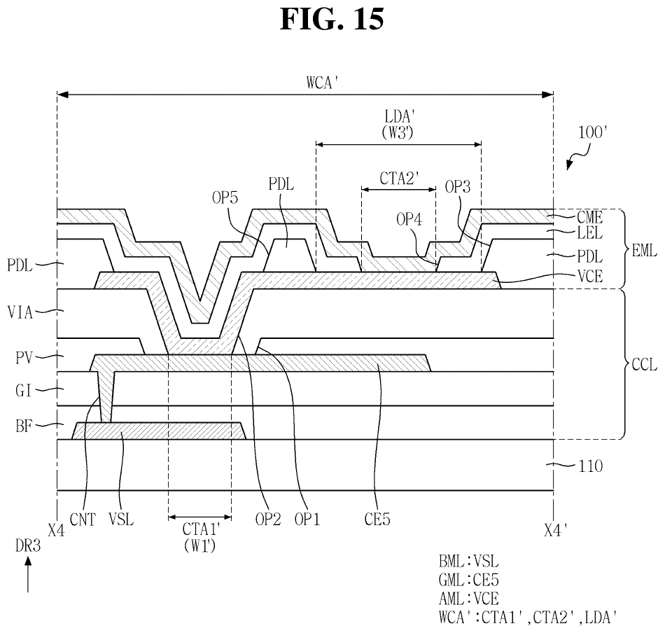

This will be described later through comparison with a comparative example of FIGS. 14 and 15.

FIG. 14 is a plan view schematically showing a part of a display area DA of a display substrate 100′ according to a comparative example. FIG. 15 is a cross-sectional view taken along line X4-X4′ of FIG. 14.

Referring to FIGS. 14 and 15 in addition to FIGS. 7 and 12, in a wiring contact area WCA′ of the display substrate 100′ according to the comparative example, a first contact area CTA1′ may not overlap a laser drilling margin area LDA′ in the third direction DR3, whereas a second contact area CTA2′ may overlap the laser drilling margin area LDA′ in the third direction DR3. For example, the second opening OP2 of the via film VIA may not overlap the third opening OP3 of the pixel defining film PDL in the third direction DR3, and the fourth opening OP4 of the light emitting layer LEL may overlap the third opening OP3 of the pixel defining film PDL in the third direction DR3.

In some embodiments, in the wiring contact area WCA′ according to the comparative example, the pixel defining film PDL may further include a fifth opening OP5 that overlaps the second opening OP2 and the first contact area CTA1′.

To prevent interference with the emission area LA, the wiring contact area WCA according to an embodiment and the wiring contact area WCA′ according to the comparative example may have the same width.

As illustrated in FIGS. 14 and 15, a width W3′ of the laser drilling margin area LDA′ may be narrowed in order to secure a width W1′ of the first contact area CTA1′, that is, the minimum margin width for forming the second opening OP2 and the fifth opening OP5 in the wiring contact area WCA′ according to the comparative example.

On the other hand, as shown in FIG. 12, since the first contact area CTA1 overlaps the laser drilling margin area LDA in the wiring contact area WCA according to an embodiment, the width of the laser drilling margin area LDA can be maximized within the wiring contact area WCA regardless of the width of the first contact area CTA1.

Therefore, it is possible to prevent interference between the emission area LA and the wiring contact area WCA, which become closer to each other in a higher-resolution panel, while securing the laser drilling process margin.

Hereinafter, other embodiments of the display device according to an embodiment will be described. In the following embodiments, description of the same components as those of the above-described embodiment, which are denoted by like reference numerals, will be omitted or simplified, and differences will be mainly described.

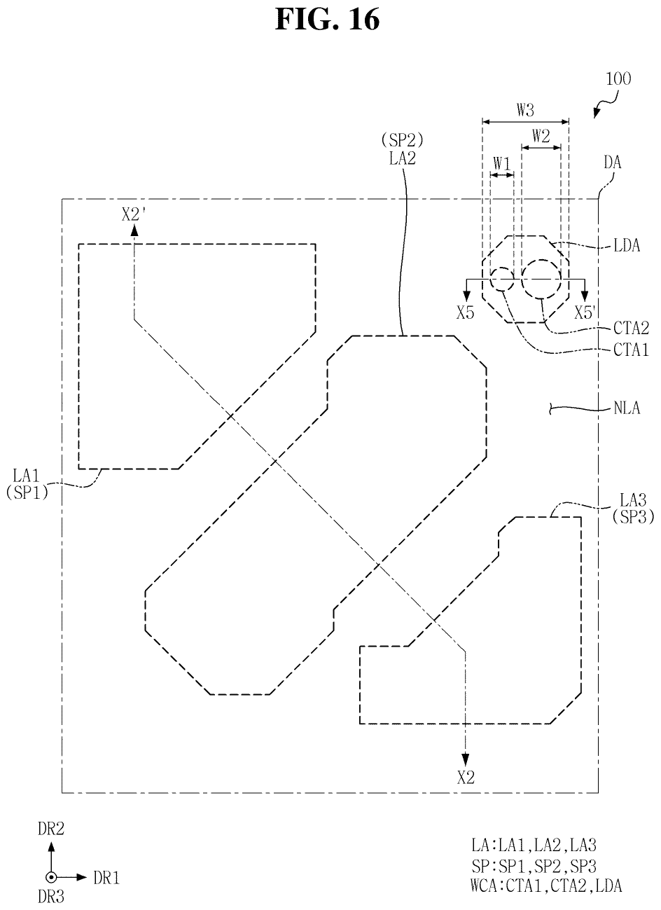

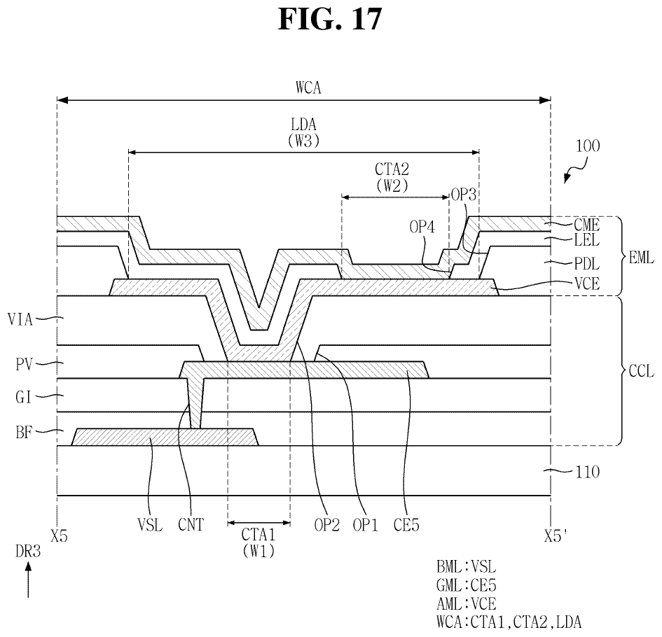

FIG. 16 is a plan view schematically illustrating a part of a display area DA of a display substrate 100 according to an embodiment. FIG. 17 is a cross-sectional view taken along line X5-X5′ of FIG. 16.

Referring to FIGS. 16 and 17, the display device 10 according to the present embodiment is different from the display device 10 according to the embodiment described with reference to FIG. 7 and the like in that the first contact area CTA1 and the second contact area CTA2 do not overlap each other.

More specifically, in the display device 10 according to the present embodiment, each of the first contact area CTA1 and the second contact area CTA2 may overlap the laser drilling margin area LDA in the third direction DR3, in the same manner as in the display device 10 according to the embodiment described with reference to FIG. 7 and the like. For example, each of the second opening OP2 of the via film VIA and the fourth opening OP4 of the light emitting layer LEL may overlap the third opening OP3 of the pixel defining film PDL in the third direction DR3. The entire first contact area CTA1 and the entire second contact area CTA2 may each be located in an area that overlaps the laser drilling margin area LDA.

However, in the display device 10 according to the present embodiment, unlike the display device 10 according to the embodiment described with reference to FIG. 7 and the like, the first contact area CTA1 and the second contact area CTA2 may not overlap each other in the third direction DR3. For example, the second opening OP2 of the via film VIA may not overlap the fourth opening OP4 of the light emitting layer LEL in the third direction DR3. Further, the first opening OP1 of the passivation film PV may not overlap the fourth opening OP4 of the light emitting layer LEL in the third direction DR3.

In this way, depending on the laser drilling process margin such as the alignment margin of the laser generator HD (see FIG. 13) and the range of the energy irradiation area of the laser LS (see FIG. 13), the position of the second contact area CTA2 may be changed in various ways within a range that overlaps the laser drilling margin area LDA.

In addition, although not shown in the drawings, in an embodiment, a part of the first contact area CTA1 may overlap only a part of the second contact area CTA2. Within the range where the first contact area CTA1 overlaps the laser drilling margin area LDA, the overlapping relationship between the first contact area CTA1 and the second contact area CTA2 may be modified in various ways.

In the present specification, the description has been mainly provided for the case where the second voltage line VSL is connected to the auxiliary electrode VCE through the fifth connection electrode CE5, but the present disclosure is not limited thereto. The second voltage line VSL may be in direct contact with the auxiliary electrode VCE at the same location as the fifth connection electrode CE5. In this case, the first contact area CTA1 may be a region in which the auxiliary electrode VCE and the second voltage line VSL are in direct contact with each other.

In concluding the detailed description, those skilled in the art will appreciate that many variations and modifications can be made to the embodiments without substantially departing from the principles of the present disclosure. Therefore, the disclosed embodiments of the inventive concept are used in a generic and descriptive sense only and not for purposes of limitation.

What is claimed is:

1. A display device comprising:
a substrate;
a first metal layer disposed on the substrate;
a first insulating film disposed on the first metal layer;
a second metal layer disposed on the first insulating film;
a pixel defining film disposed on the second metal layer;
a light emitting layer disposed on the pixel defining film;
a third metal layer disposed on the light emitting layer; and
a plurality of light emitting elements comprising a first electrode disposed in the second metal layer, a second electrode disposed in the third metal layer, and a light emitting material disposed in the light emitting layer, wherein
the first metal layer comprises a first voltage line providing a first voltage to the second electrode,
the first insulating film comprises a first opening extending to at least a part of a top surface of the first voltage line,
the second metal layer comprises an auxiliary electrode connected to the first voltage line through the first opening,
the pixel defining film comprises a second opening extending to at least a part of a top surface of the auxiliary electrode,
the light emitting layer comprises a third opening extending to at least a part of the top surface of the auxiliary electrode,
the second electrode is connected to the auxiliary electrode through the second opening and the third opening, and
each of the first opening and the third opening overlaps the second opening.

2. The display device of claim 1, wherein each of an entire portion of the first opening and an entire portion of the third opening overlaps the second opening.

3. The display device of claim 1, wherein each of a width of the first opening and a width of the third opening is smaller than a width of the second opening.

4. The display device of claim 1, wherein at least a part of the first opening overlaps the third opening.

5. The display device of claim 4, wherein an entire portion of the first opening overlaps the third opening.

6. The display device of claim 1, wherein the first opening and the third opening do not overlap.

7. The display device of claim 1, wherein the third opening is formed by a laser drilling process.

8. The display device of claim 7, wherein the first opening and the second opening are formed by a photolithography process.

9. The display device of claim 1, further comprising a second insulating film disposed between the first metal layer and the first insulating film,
wherein the second insulating film comprises a fourth opening extending to at least a part of the top surface of the first voltage line, and
a width of the fourth opening is greater than a width of the first opening.

10. The display device of claim 9, wherein the auxiliary electrode is not in contact with the second insulating film.

11. The display device of claim 1, wherein the light emitting layer is disposed entirely over the plurality of light emitting elements.

12. A display device comprising:
a substrate;
a light emitting element layer disposed on the substrate, and comprising:
a plurality of light emitting elements comprising a first electrode, a light emitting layer disposed on the first electrode, and a second electrode disposed on the light emitting layer; and
a pixel defining film extending to at least a part of a top surface of the first electrode;
a first voltage line disposed between the substrate and the light emitting element layer, and providing a first voltage to the second electrode; and
an auxiliary electrode disposed in a same layer as the first electrode, and connecting the first voltage line to the second electrode,
wherein the second electrode and the auxiliary electrode are in contact with each other through a first opening of the pixel defining film and a second opening of the light emitting layer, and
each of a first region where the first voltage line and the auxiliary electrode are in contact with each other and a second region where the second electrode and the auxiliary electrode are in contact with each other overlaps a third region where the first opening is disposed.

13. The display device of claim 12, wherein each of an entire portion of the first region and an entire portion of the second region overlaps the third region.

14. The display device of claim 12, wherein each of a width of the first region and a width of the second region is smaller than a width of the third region.

15. The display device of claim 12, wherein at least a part of the first region overlaps the second region.

16. The display device of claim 15, wherein an entire portion of the first region overlaps the second region.

17. The display device of claim 12, wherein the first region and the second region do not overlap.

18. The display device of claim 12, wherein the second region is formed by a laser drilling process.

19. The display device of claim 18, wherein the first region and the third region are formed by a photolithography process.

20. The display device of claim 12, wherein the light emitting layer is disposed entirely over the plurality of light emitting elements.
